(19) United States
(12) Patent Application Publication
(10) Pub. No.: US 2019/0199340 A1
(43) Pub. Date: Jun. 27, 2019

(54) METHOD AND APPARATUS FOR CONTROL OF INPUT CURRENT OF HIGH-CURRENT AND HIGH-VOLTAGE APPLICATIONS

(71) Applicant: NOKIA SOLUTIONS AND NETWORKS OY, Espoo (FI)

(72) Inventor: Martin PLESNIK, Ottawa (CA)

(73) Assignee: Nokia Solutions and Networks Oy

(21) Appl. No.: 15/852,811

(22) Filed: Dec. 22, 2017

(51) Int. Cl. H03K 17/081

(52) U.S. Cl. CPC H03K 17/081

(57) ABSTRACT

Various embodiments relate to a method and apparatus for controlling current from a power source to a load, the apparatus including a first electronic switch connected between said power source and said load, a second electronic switch connected in series with a resistive device wherein the series connected combination is connected between said power source and said load, a pulse generator which provides a pulse of a predetermined length and control circuitry connected to said pulse generator, wherein said control circuitry at the commencement of a pulse from said pulse generator enables said second electronic switch and wherein said control circuitry at the cessation of said pulse applies a test condition and enables said first electronic switch when the test condition is met.

### TECHNICAL FIELD

This disclosure relates generally to regulation of input current on electronic circuit boards, and more specifically, but not exclusively, to regulation of both inrush current and current fault.

### BACKGROUND

Several methods for controlling the inrush current are known. For example, a Metal-Oxide Semiconductor Field Effect Transistor (“MOSFET”) controlled using a feedback circuit consisting of a resistor connected, in series, with a capacitor which are connected across the MOSFET's drain and gate.

In the example, the feedback circuit is added in parallel to the MOSFET's parasitic Miller (drain-to-gate) capacitor. During the inrush current regulation event, the current through this feedback circuit forces the gate voltage to oppose the driving signal, forcing virtually constant drain current (i.e., constant inrush current).

This example is illustrated, in U.S. Pat. No. 9,513,681 B2, where the feedback circuit described above including a resistor and capacitor was replaced by a “virtual Miller capacitor”, which is a circuit including an amplifier, and current source.

Disadvantages of both of these solutions are that the inrush current control MOSFET serves to conduct both the circuit board inrush current and circuit board operating current and therefore, a compromise between the MOSFET's on-resistance and Safe Operating Area (“SOA”) characteristics needs to be found. As a result, in using these methods, the best MOSFETs, in terms of on-resistance cannot be used leading to high losses generated by the board operating current.

Another disadvantage of these two solutions is that the design problem of forcing the MOSFET to operate inside its SOA is solved by approximation only, which introduces risks of component underrating and component failure.

Another disadvantage of the above two solutions is that searching for an optimal MOSFET is difficult in high-current and high-voltage applications, as thermal problems caused by the on-resistance losses can be solved be paralleling of multiple MOSFETs, however, the same strategy (i.e., connecting multiple MOSFETs in parallel) cannot be used as it would lead to a high-cost complex solution when controlling the inrush current.

In U.S. Pat. No. 8,560,137, the process of charging the input capacitor was separated into a sequence of pre-charging intervals during which the input capacitor voltage was increased by a particular voltage such that the SOA of the MOSFET was not violated (“staggered charging”). However, with this solution the selection of the MOSFET was difficult as the MOSFET SOA may need to be over-rated leading to higher on-resistance losses during the system's normal operation and further setting the dead times between particular charging events may be difficult because the dead time depends also on the cooling characteristics of the MOSFET assembly. In the case of large dead time intervals, the input capacitor voltage may drop substantially resulting in partial loss of the advantage of the staggered charging. Finally, another disadvantage is that the controller is complex which leads to larger board real-estate and a higher component cost.

In U.S. Pat. Nos. 5,519,264; 6,646,842; 6,737,845; 6,744,612 and 8,237,420, a resistive device is added in parallel to the MOSFET to remove the thermal stress from the MOSFET. Initially, the resistive device may conduct the inrush current while the MOSFET is turned off, then when the MOSFET is turned on, the MOSFET provides low impedance between the input and circuit load.

However, disadvantages with these solutions include handling the MOSFET switching resulting in a secondary inrush current spike. Specifically, the secondary inrush current spike is caused by the voltage across the MOSFET which is not zero at the time when the MOSFET is forced to turn on, leading to a significant current spike which propagates through the board in the input current path. The current spike can harm the MOSFET as well as cause problems on neighboring circuit boards when operating in shelf systems.

A cause for the non-zero voltage across the MOSFET is board leakage current. Board leakage current may result from signaling devices, voltage sensing and monitoring circuits, and also from power converters which see input voltage but are not enabled to operate. Other causes for the non-zero voltage across the MOSFET are methods for determining the MOSFET turn on time. Particularly, solutions are based either on the fixed time delay for charging the input capacitor or on monitoring voltage across the input capacitor which do not provide enough information to determine accurately the switching time.

Another disadvantage of these solutions includes creating a permanent current path through the resistive device allowing current to flow from an external source of power to the circuit board, even in fault conditions (e.g., short circuit current). To comply with safety requirements, this current path should be disconnected at the fault conditions.

### SUMMARY OF EXEMPLARY EMBODIMENTS

A brief summary of various embodiments is presented below. Embodiments address the need to create an input current control for the regulation of inrush current and current fault on electronic circuit boards.

In order to overcome these and other shortcomings of the prior art and in light of the present need to create a method and apparatus for control of input current for the regulation of the inrush current and current fault on electronic circuit boards, a brief summary of various exemplary embodiments is presented. Some simplifications and omissions may be made in the following summary, which is intended to highlight and introduce some aspects of the various exemplary embodiments, but not to limit the scope of the invention.

Detailed descriptions of a preferred exemplary embodiment adequate to allow those of ordinary skill in the art to make and use the inventive concepts will follow in later sections.

Various embodiments described herein relate to an inrush current controller for controlling current from a power source to a load including a first electronic switch connected between said power source and said load, a second electronic switch connected in series with a resistive device wherein the series connected combination is connected between said power source and said load, a pulse generator which provides a pulse of a predetermined length and control circuitry connected to said pulse generator, wherein said control circuitry at the commencement of a pulse from said pulse generator enables said second electronic switch and wherein said control circuitry at the cessation of said pulse applies a test condition and enables said first electronic switch when the test condition is met.

In an embodiment of the present disclosure, said test condition comprises determining if the voltage across said first electronic switch is below a predetermined level.

In an embodiment of the present disclosure, said first electronic switch is a first MOSFET.

In an embodiment of the present disclosure, said control circuitry enables said first MOSFET by modulating the associated gate voltage of said first MOSFET.

In an embodiment of the present disclosure, said inrush current controller further having a current sensing resistor connected in series with the first electronic switch wherein the series connected combination is connected between the power source and the load.

In an embodiment of the present disclosure, said enabling of the first electronic switch is modulated to keep the power dissipation of the first electronic switch below a predefined limit.

In an embodiment of the present disclosure, said enabling of the first electronic switch is modulated to keep the current through the first electronic switch below a predefined limit.

In an embodiment of the present disclosure, said first electronic switch and said second electronic switch are configured to be on the positive voltage rail between the power source and the load.

In an embodiment of the present disclosure, said first electronic switch and said second electronic switch are configured to be on the negative voltage rail between the power source and the load.

Various embodiments described herein relate to a method for controlling current from a power source to a load, including generating, by a pulse generator, a pulse of a predetermined length; and controlling, by control circuitry, a first electronic switch between said power source and said load and a second electronic switch in series with a resistive device wherein the series connected combination is connected between said power source and said load further including enabling said second electronic switch at the commencement of a pulse from said pulse generator, applying a test condition at the cessation of said pulse and enabling said first electronic switch when the test condition is met.

In an embodiment of the present disclosure, said test condition comprises determining if the voltage across said first electronic switch is below a predetermined level.

In an embodiment of the present disclosure, said first electronic switch is a first MOSFET.

In an embodiment of the present disclosure, said control circuitry enables said first MOSFET by modulating the associated gate voltage of said first MOSFET.

In an embodiment of the present disclosure, said inrush current controller further having a current sensing resistor connected in series with the first electronic switch wherein the series connected combination is connected between the power source and the load.

In an embodiment of the present disclosure, said control circuitry enabling the first electronic switch so as to keep the power dissipation of the first electronic switch below a predefined limit.

In an embodiment of the present disclosure, said control circuitry enabling the first electronic switch so as to keep the current through the first electronic switch below a predefined limit

In an embodiment of the present disclosure, said first electronic switch and said second electronic switch are configured to be on the positive voltage rail between the power source and the load.

In an embodiment of the present disclosure, said first electronic switch and said second electronic switch are configured to be on the negative voltage rail between the power source and the load.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

These and other more detailed and specific features are more fully disclosed in the following specification, reference being had to the accompanying drawings, in which:

FIG. 1A illustrates a circuit diagram of the inrush current controller;

FIG. 1B illustrates a timing diagram of the inrush current controller from FIG. 1A;

FIG. 2 illustrates a circuit diagram of a current embodiment of an inrush current controller;

FIG. 3 illustrates a timing diagram of the inrush current controller from FIG. 2;

FIG. 4 illustrates a circuit diagram of an alternate embodiment of an inrush current controller where the inrush current controlling devices are placed in the positive power rail; and

FIG. 5 illustrates a flow chart for a method for regulation of inrush current and current fault.

### DETAILED DESCRIPTION OF THE INVENTION

It should be understood that the figures are merely schematic and are not drawn to scale. It should also be understood that the same reference numerals are used throughout the figures to indicate the same or similar parts.

The descriptions and drawings illustrate the principles of various example embodiments. It will thus be appreciated that those skilled in the art will be able to devise various arrangements that, although not explicitly described or shown herein, embody the principles of the invention and are included within its scope. Furthermore, all examples recited herein are principally intended expressly to be for pedagogical purposes to aid the reader in understanding the principles of the invention and the concepts contributed by the inventor to furthering the art, and are to be construed as being without limitation to such specifically recited examples and conditions. Additionally, the term, “or,” as used herein, refers to a non-exclusive or (i.e., and/or), unless otherwise indicated (e.g., “or else” or “or in the alternative”). Also, the various embodiments described herein are not necessarily mutually exclusive, as some embodiments can be combined with one or more other embodiments to form new embodiments. Descriptors such as “first,” “second,” “third,” etc., are not meant to limit the order of elements discussed, are used to distinguish one element from the next, and are generally interchangeable.

In frequently used solutions, a MOSFET is used to regulate the inrush current. An advantage of this invention comes from the replacement of the MOSFET as an inrush current regulator, by a PTC or NTC device. This replacement eliminates the ambiguities associated with the MOSFET selection, removes the risk of MOSFET failures, makes the inrush control circuit reliable while reducing component costs, reduces power losses, and saves the board real-estate.

Comparing the controllers which are available on the market, the complexity of the solution in the embodiments described herein is reduced substantially. This is achieved by replacing the complex primary inrush current power computation subsystem from the controller by a simple control for the MOSFET operating as a switch.

Solutions which are based on the use of resistive current limiting device suffer from the secondary inrush current spikes problem as well as from the problem of permanent connection to the external power source. The current embodiment solves both these problems and introduces a general method for controlling input current suitable for majority of industrial applications.

Because of the issues of existing solutions described above, there is a need for a method and apparatus for regulation of the inrush current and current fault on electronic circuit boards.

Inrush current is current flowing from an external power source into a circuit board during a short period of time, either when the external power supply is turned on providing an input voltage to the circuit board or when the circuit board is inserted into a live system. The magnitude of the inrush current mainly depends on the amount of capacitance connected across the card's input feeds (i.e., input capacitor) and magnitude of the input voltage.

Fault current may develop on the circuit board either as a consequence of the board overloading, component failure or human mistake/error at various steps of the board's life including testing, installation and programming.

If a fault occurs, it is expected that the input current control circuit will limit the magnitude of the input current and disconnect the board from the source of the external power.

Failure to regulate the inrush current may lead to overloading the external power supply system resulting, in over-current shut down of entire system.

Further, by failing to regulate the inrush current, a disturbance generated by the inrush current may propagate throughout the system backplane and cause malfunction of neighboring circuit boards when operating in shelf systems and the stress originated by an excessive inrush current may lead to failure of other components residing on the host electronic circuit boards.

The current embodiment solves the problem of regulation of the input current on electronic circuit boards, including the regulation of both inrush current and current fault by routing the inrush current and the operating current through two different paths while using different current control concepts in each of these two paths.

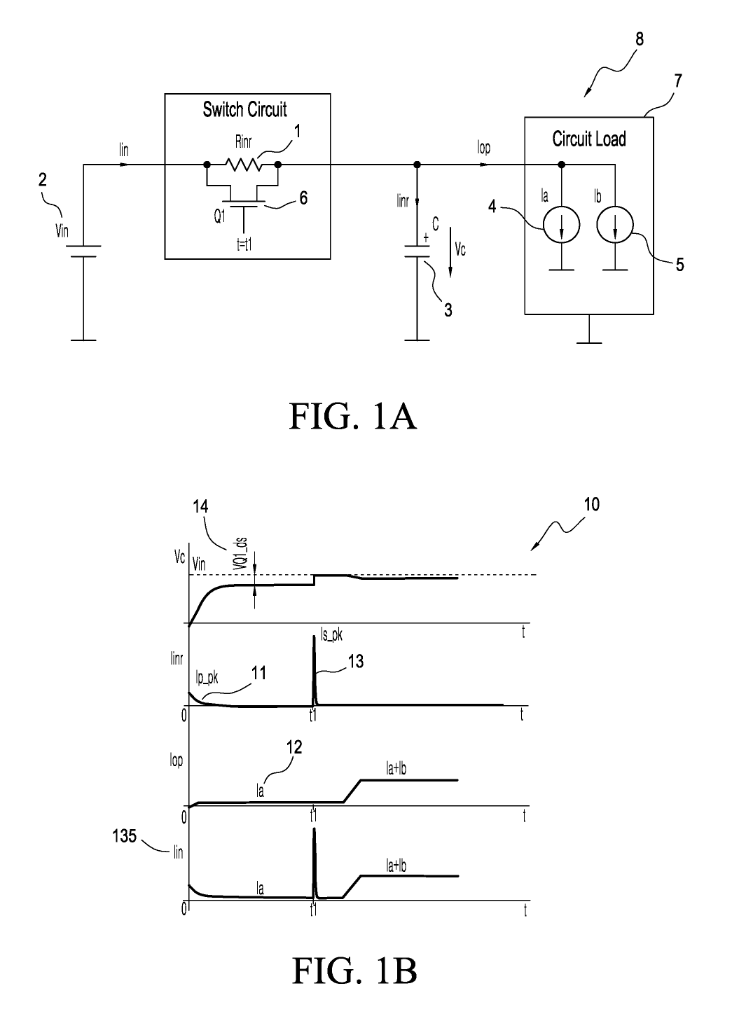

Circuit diagram 8 depicted in FIG. 1A is used to illustrate the concept of the primary and secondary inrush currents. The resistor Rᵢₙᵣ 1 serves to limit the inrush current flowing from the input voltage source Vᵢₙ 2 to the input capacitor C 3. The current source Iₐ 4 represents the circuit load leakage current and current source I_{b} 5 represents the current developed by normal operation of the circuit load e.g., by operation of microprocessors, memories, transmitters, amplifiers etc.

After the input voltage Vᵢₙ is applied, the current flows from the input voltage source Vᵢₙ 2 through the resistor Rᵢₙᵣ 1 into the input capacitor C 3 and circuit load 7 while the MOSFET Q₁ 6 is held in the off state. Transient of the current flowing into the capacitor C 3 during this phase of the circuit operation is referred to as the primary inrush current.

Assuming an initial zero voltage across the input capacitor C 3 at the instant of applying the input voltage Vᵢₙ 2, the peak primary inrush current Iₚ_{_}ₚₖ depends on the input voltage source Vᵢₙ 2 and the resistor Rᵢₙᵣ 1 as shown in (1).

From the instant of applying the input voltage Vin 2, the voltage across the input capacitor C 3 is increasing and voltage across the MOSFET Q₁ 6 is decreasing, such that V_{Q1}_{_}_{ds}(t)=Vᵢₙ−V_{c}(t).

After the primary inrush current dies out, the MOSFET Q₁ 6 is turned on causing another transient, referred to as the secondary inrush current.

FIG. 1B depicts a timing diagram 10 showing critical waveforms of voltages and currents associated with operation of the circuit from FIG. 1A.

After the input voltage Vᵢₙ is applied, the primary inrush current spike 11 is developed. The inrush current Iᵢₙᵣ flowing into the capacitor C first peaks-up achieving the Iₚ_{_}ₚₖ value and then decreases which is illustrated as the exponentially falling segment on the waveform of the inrush current lᵢₙᵣ 11.

At the end of the primary inrush current transient (i.e. at time t₁) inrush current lᵢₙᵣ approaches to zero. However, due to the leakage current lₐ 12 flowing through the resistor Rᵢₙᵣ, voltage across the MOSFET Q₁, V_{Q1}_{_}_{ds} 14 as shown in (4) is not a zero. Therefore, turning the MOSFET Q₁ on at the time t₁ originates a significant secondary inrush current spike 13 of a magnitude of Iₛ_{_}ₚₖ.

In order to limit the primary inrush current, the resistance of the Rᵢₙᵣ 1 is on in the order of tens or hundreds of Ohms. In order to conduct the circuit load operating current while reducing power losses, a MOSFET Q₁ 6 is used which has a low resistance, on the order of m□ or tens of m□. For example, assuming the Vᵢₙ voltage of 48V and a 50□ resistor Rᵢₙᵣ and using (1), the primary inrush current spike Iₚ_{_}ₚₖ can be 0.96 A. Also, assuming the circuit load leakage current lₐ of 40 mA, a 2V voltage drop across the MOSFET Q₁ can be computed using (4). Further, assuming a 10 mOhm resistance in the path of current flowing from the voltage source into the input capacitor C (including resistance of the MOSFET Q₁ when turned on), magnitude of the secondary inrush current spike of Iₛ_{_}ₚₖ may be as high as 200 A.

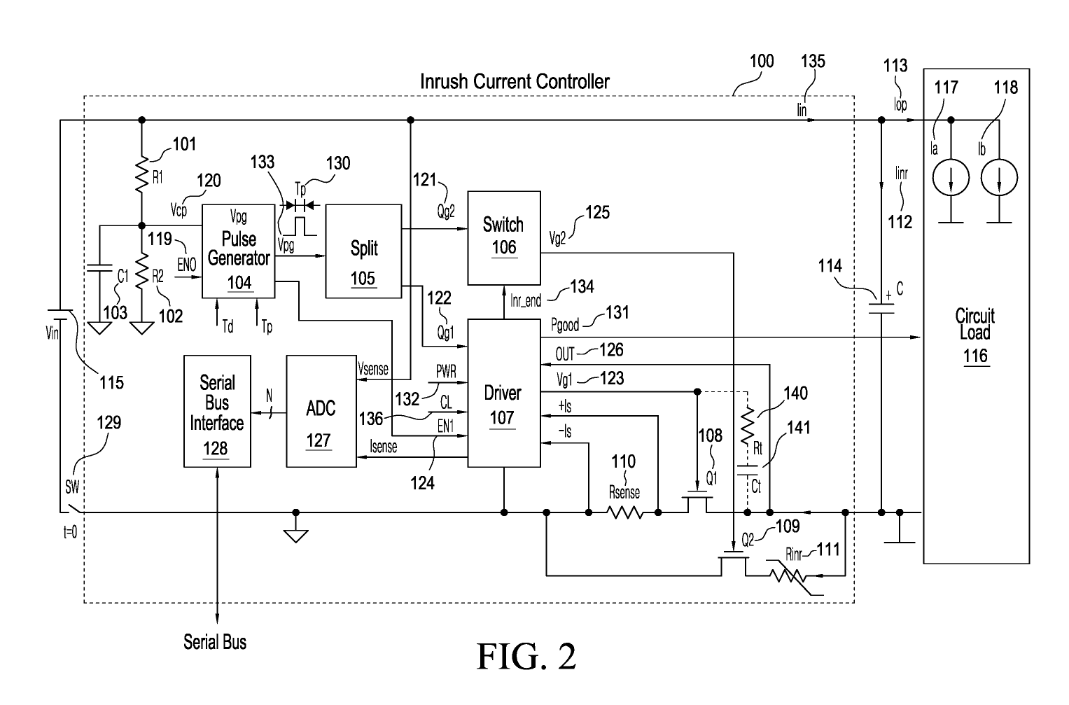

FIG. 2. illustrates the inrush current controller 100 including resistor R₁ 101, resistor R₂ 102, capacitor C₁ 103, pulse generator 104, split block 105, switch 106, driver 107, MOSFET Q₁ 108, MOSFET Q₂ 109, current sensing resistor Rₛₑₙₛₑ 110 and current limiting resistive device Rᵢₙᵣ 111.

Inrush current Iinr 112 flows into input capacitor C 114. During the primary inrush current phase, the inrush current lᵢₙᵣ 112 and the circuit load leakage current lₐ 117 flow through the MOSFET Q₂ 109 and resistive device Rᵢₙᵣ 111 while the MOSFET Q₁ 108 is turned off. During the secondary inrush current phase, the inrush current lᵢₙᵣ 112 and leakage current lₐ 117 flow mainly through the MOSFET Q₁ 108 and current sensing resistor Rₛₑₙₛₑ 110 while the path consisting of the MOSFET Q₂ 109 and the resistive device Rᵢₙᵣ 111 is still conductive. During the circuit load's 116 normal operation, currents lₐ 117 and l_{b} 118 flow through the MOSFET Q₁ 108 and current sensing resistor Rₛₑₙₛₑ 110 while the MOSFET Q₂ 109 is turned off. At fault conditions, both MOSFET Q₁ 108 and MOSFET Q₂ 109 are turned off.

The circuit load leakage current Iₐ 117 flows into the circuit load 116 when the circuit load 116 is not enabled to operate. The circuit load leakage current Iₐ 117 and the circuit load current I_{b} 118 flow into the circuit load 116 when it is enabled to operate.

The divider consisting of resistor R₁ 101, resistor R₂ 102 and the filter capacitor C₁ 103 senses the input voltage Vᵢₙ 115. The output from this resistor divider V_{cp} 120 is connected to the pulse generator 104. The operation of the pulse generator 104 can be gated by the enable signal EN0 119.

The output of the pulse generator 104 is connected to the split block 105 which generates control signals Q_{g2} 121 and Q_{g1} 122 for the switch 106 and the driver 107, respectively. The operation of the driver 107 can be gated by the enable signal EN1 124 generated by the pulse generator 104. The operation of the switch 106 can be controlled by the signal Inr_end 134 generated by the driver 107.

The output of the switch V_{g2} 125 is connected to the gate of the MOSFET Q₂ 109. The output of the driver V_{g1} 123 is connected to the gate of the MOSFET Q₁ 108.

The driver 107 can sense both the drain-to-source voltage across the MOSFET Q₁ 108, which is OUT 126, and voltage across the current sensing resistor Rₛₑₙₛₑ 110 providing the information about the drain current flowing through MOSFET Q₁ 108, which is IQ1_d.

The driver 107 can modulate voltage V_{g1} 123 such that either power dissipated by the MOSFET Q₁ 108 or current flowing through is less than the pre-defined limit value PWR 132 and CL 136 respectively.

Modulation of the voltage V_{g1} 123 is gated by the signal Q_{g1} 122 generated by the split block 105.

The ADC 127 block is connected to the input feed as well as to the driver 107 to sense the board input voltage Vᵢₙ 115 and input current Iᵢₙ 135, respectively. The output from the ADC 127 block is connected to serial bus interface block 128 which facilitates the communication with a system up-stream controller.

Resistor Rₜ 140 and capacitor Cₜ 141 are connected across the gate and drain of the MOSFET Q1 108. These devices are optional and can complement the function of controlling current flowing through the MOSFET Q1 108.

An enable signal entering a pulse generator allows the controller to completely disconnect the circuit load from the source of input voltage Vᵢₙ.

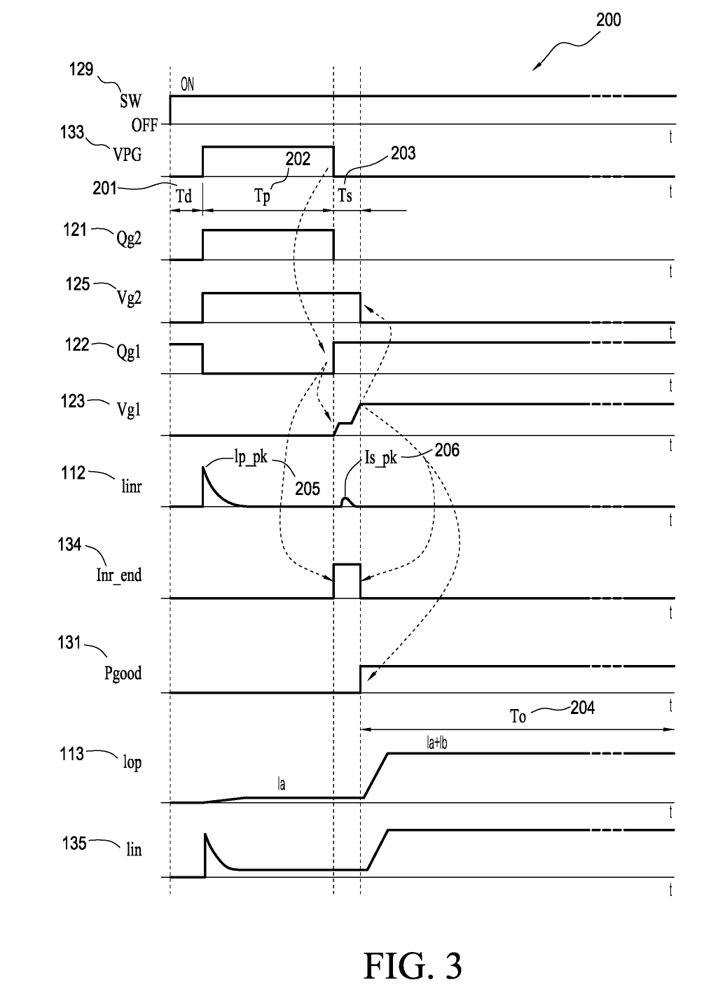

FIG. 3 illustrates a timing diagram 200 of the inrush current controller.

The switch SW 129 is turned on at time t=0. After the switch SW 129 is on, the voltage V_{cp} 120 at the input of the pulse generator 104 rises. After a delay T_{d} 201, the V_{cp} 120 reaches a threshold level preset inside the pulse generator 104. At this instant the T_{d} interval 201 expires and the pulse generator 104 releases a pulse of the length of Tₚ 130.

The delay T_{d} 201 can be adjusted using either of resistor R₁ 101, resistor R₂ 102, capacitor C₁ 103 or by adjusting the threshold level for the voltage V_{cp} 120 inside the pulse generator 104.

The T_{d} delay interval 201 can be also extended by disabling the pulse generator 104 operation via its input EN0 119.

During the initial T_{d} interval 201, the pulse generator 104 sets its output V_{pg} 133 low which forces the split block 105 to set Q_{g2} 121 low forcing V_{g2} 125 low which turns the MOS FET Q₂ 109 off. Also, the pulse generator 104 disables the driver's output V_{g1} 123 using the signal EN1 124 which forces the MOSFET Q₁ 108 to the off state. The signal EN1 124 has a higher precedence over the signal Q_{g1} 122, therefore, the state of signal Q_{g1} 122 has no impact on the state of V_{g1} 123 when the signal EN1 124 is active.

After the T_{d} interval 201 expires, the Tₚ interval 202 launches. The length of the Tₚ interval 202 is determined by the width of the pulse generated by the pulse generator 104 on its output V_{pg} 133. The Tₚ interval 202 corresponds to the primary inrush current phase.

During the Tₚ interval 202, the pulse generator 104 sets the driver's input EN1 124 to enable the V_{g1} 123 modulation. Also, the pulse generator' output V_{pg} 133 is set high which forces the split block 105 to set Q_{g2} 121 high forcing the switch 106 to set V_{g2} 125 high, and set Q_{g1} 122 low forcing the driver 107 to set the V_{g1} 123 low. Consequently, Q₁ 108 stays off and Q₂ 109 is turned on. At this point, the primary inrush current control phase begins. The primary inrush current Iᵢₙᵣ 112 flows through MOSFET Q₂ 109 and Rᵢₙᵣ 111.

Assuming a negligible on-resistance of the MOSFET Q₂ 109 comparing to the resistance Rᵢₙᵣ, the resistive device Rᵢₙᵣ 111 limits the inrush current. Therefore, the magnitude of the peak inrush current Iₚ_{_}ₚₖ 205 can be computed as:

Iₚ_{_}ₚₖ=Vᵢₙ/Rᵢₙᵣ. (1)

The pulse length Tₚ 130 can be set as follows:

Tₚ>5/(Rᵢₙᵣ*C). (2)

Length of the Tₚ 202 interval is an adjustable parameter. This parameter can be implemented various ways (e.g. by installing a timing capacitor inside the pulse generator block 104).

During the Tₚ interval 202, it applies that the voltage across the drain and source of the MOSFET Q₁ 108 is:

ΔV_{Q1}_{_}_{ds}(t)=Rᵢₙᵣ>*(Iᵢₙᵣ(t)+Iₐ(t)) (3)

Towards the end of the Tₚ interval 202, the inrush current component Iᵢₙᵣ in (3) above approaches to zero and the leakage current Iₐ settles to Iₐ_{_}ₛ. Therefore, the voltage across the drain and source of the MOSFET Q₁ 108 can be expressed as:

ΔV_{Q1}_{_}_{ds}=Rᵢₙᵣ>*Iₐ_{_}ₛ (4)

In real applications, the leakage current Iₐ_{_}ₛ is not a zero implying a non-zero voltage across the MOSFET Q₁ (4).

If the voltage across the MOSFET Q₁ ΔV_{Q1}_{_}_{ds} at the end of the Tₚ interval 202 is larger than a predefined limit, then the driver 107 hold P_{good} output 131 low and enter an idle mode. The circuit load 116 is not allowed to operate.

If the voltage across the MOSFET Q₁ ΔV_{Q1}_{_}_{ds} at the end of the Tₚ interval 202 is smaller than a predefined limit, then the controller 100 operation continues by launching the Tₛ interval 203. The Tₛ interval 203 corresponds to the secondary inrush current phase.

The Tₛ interval 203 launches at the time when the pulse generator 104 sets its output V_{pg} 133 low forcing Q_{g1} 122 high and Q_{g2} 121 low. As a consequence, the driver 107 sets the Iₙᵣ_{_}_{end} 134 high commanding the switch 106 to keep its output Vg2 125 high which allows the MOSFET Q₂ to stay on. The high level on the Q_{g1} 122 enables the driver 107 to gradually increase the V_{g1} voltage 123 and regulate MOSFET's Q₁ 108 channel resistance (by modulating Vg1 voltage 123) such that either power dissipated by this MOSFET or current flowing through can be less than a pre-defined limit value.

The Tₛ interval 203 expires when the V_{g1} voltage 123 reaches its pre-set maximum value. At this instant, the MOSFET Q₁ 108 is completely on, and signal Iₙᵣ_{_}_{end} 134 is set low forcing the V_{g2} low followed by turning the MOSFET Q₂ 109 off. Also, the P_{good} 131 signal is generated enabling the circuit load normal operation.

After the Tₛ interval 203 expires, the Tₒ interval 204 launches. During the Tₒ interval 204, the MOSFET Q₁ 108 is on and the circuit load enters the system boot-up phase and starts to execute application programs. Thus, the circuit load operation current 113, except the leakage current Iₐ 117, includes also component I_{b} 118 which is associated with the operation of power supplies, microprocessors, memories and other devices contained within the circuit load 116.

An over-current fault condition is detected by monitoring the circuit board's input current by driver 107 using the resistor Rₛₑₙₛₑ 110. When a fault occurs, the driver 107 initiates turning the MOSFET Q₁ 108 off.

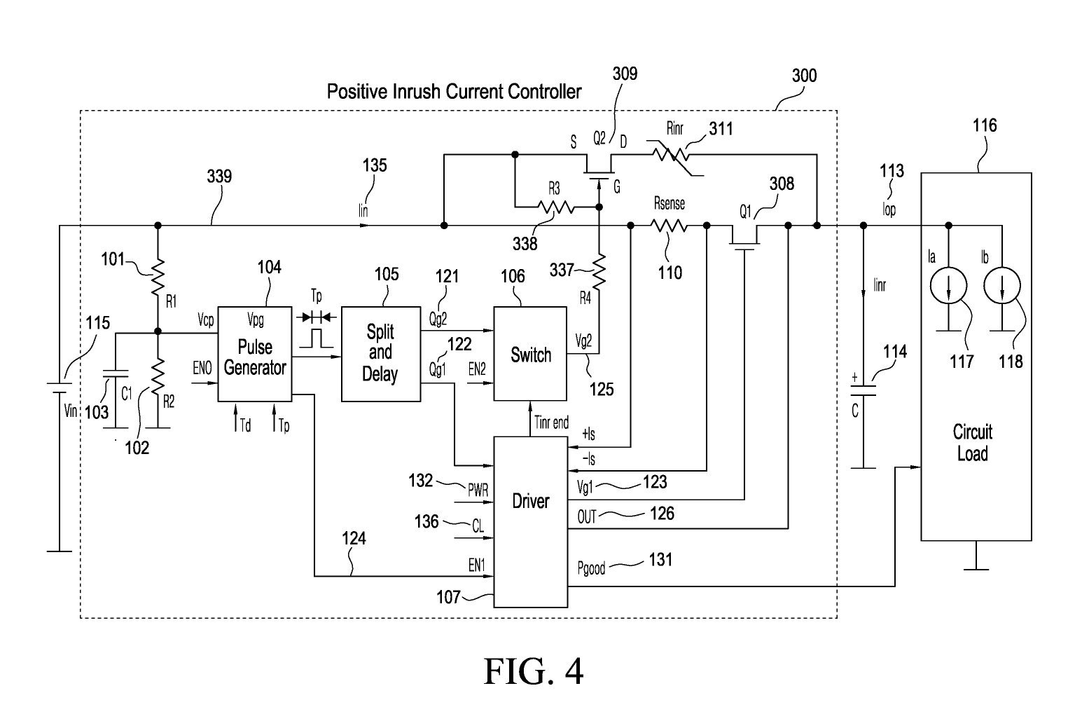

FIG. 4 illustrates an alternate embodiment where the input current controlling devices are placed in the positive power rail, which is a positive inrush current control circuit 300. This embodiment operates similar to the embodiment shown in FIG. 2 and, therefore, its description is reduced to only those functions which are necessary to clarify differences. Specifically, the MOSFET Q₂ 309, comparing to the NMOS Q₂ 109, can be a PMOS device connected to the positive input line 339 using its source terminal S and to the current limiting resistive device Rᵢₙᵣ 311 using its drain terminal D. Also, resistor R₃ 338 connecting the gate G and source S terminals of the MOSFET Q₂ 309 and resistor R₄ 337 connecting the gate terminal G of the MOSFET Q₂ 309 with output of the switch 106 are needed for operation of the MOSFET Q₂ 309. Also, the driver includes a level-shift device to modulate gate of the MOSFET Q₁ 308. Further, comparing to the V_{g2} 125 signal, the polarity of the V_{g2} 125 signal is of the opposite logic to support the operation of the MOSFET Q₂ 309.

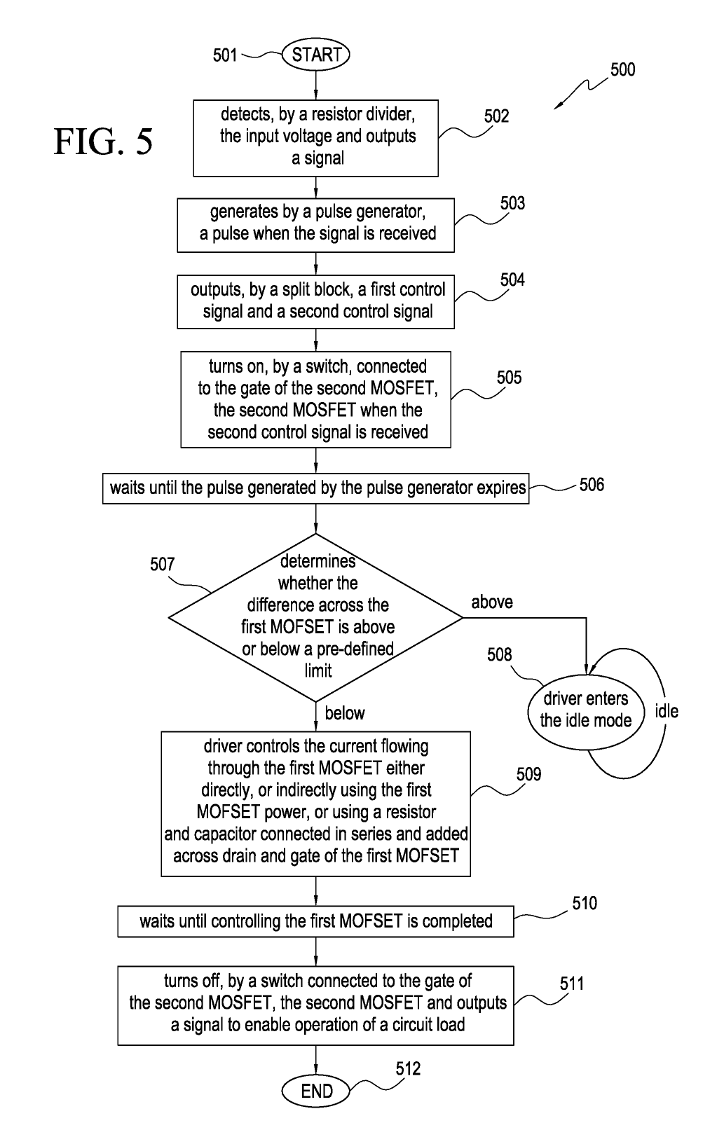

FIG. 5 illustrates a method 500 for controlling inrush current.

The method 500 begins at step 501.

The method 500 proceeds to step 502 which detects, by a divider, the input voltage and outputs a signal, forcing both a first MOSFET and a second MOSFET off.

The method 500 then proceeds to step 503 which generates, by a pulse generator, a pulse when the signal is received.

The method 500 then proceeds to step 504 which outputs, by a split block, a first control signal and a second control signal.

The method 500 then proceeds to step 505 which turns on, by a switch connected to the gate of the second MOSFET, the second MOSFET when the second control signal is received. The inrush current is being limited, by a passive current limiting device (e.g. PTC) which is connected to the second MOSFET.

The method 500 then proceeds to step 506 where the voltages V_{g1} and V_{g2} are not changed until the pulse generated by the pulse generator expires.

The method 500 then can proceed to step 507 which determines whether the voltage across the first MOSFET is above or below a predefined limit.

If the voltage across the first MOSFET is above a predefined limit, then the method proceeds to step 508 where the driver enters an idle mode.

If the voltage across the first MOSFET is below a predefined limit, the method can proceed to step 509 where the driver can either sense the current flowing through the MOSFET or determine the first MOSFET power, and gradually increasing the voltage V_{g1} regulates the gate voltage of the first MOSFET either using the current flowing through the first MOSFET or the first MOSFET power such that current flowing through the first MOSFET does not exceed a pre-defined limit. Alternatively, the current flowing through the first MOSFET can be regulated using a resistor in series with a capacitor connected across the drain and gate of the first MOSFET.

The method 500 then proceeds to step 510 where the second MOSFET is held on until controlling the first MOSFET is completed, i.e. until the gate of the first MOSFET reaches a pre-set maximum value.

The method 500 then proceeds to step 511 which turns off, by a switch connected to the gate of the second MOSFET, the second MOSFET and outputs a signal to enable operation of a circuit load.

The method 500 then proceeds to end at step 512.

The inrush current controller 100 is applicable to variety of industrial applications including wireless, optical and wirelines telecom industry, data processing, data storage, and automotive and aerospace systems including high-voltage and high-current applications.

The inrush currents through the MOSFET, PTC, and NTC thermistors were numerically analyzed and experimentally verified in the lab which removes the uncertainty and risks from the method and design. Furthermore, the procedure for selecting the PTC or the NTC device is simple and accurate.

PTC thermistors can be preferred to limit the inrush current because they are available on the market, less cost, more robust, and a smaller size. Further, in contrast to NTC devices, resistance of the PTC device rises as its temperature increases.

Since the primary inrush current is controlled by the resistive device, instead of the MOSFET, associated power is dissipated by this resistive device. Consequently, a small low-cost MOSFET Q₂ can be used. Since this MOSFET operates as a switch, the control of this MOSFET is substantially reduced to executing a simple discrete-switch function. The result is a straightforward small-size low-cost implementation. Especially with the positive inrush current control, a PMOS FET can be used to remove complexity from the controller design.

Routing the circuit load operating current in a path which is separated from the primary inrush current path allows for deploying the MOSFETs with the lowest on-resistance. This results in lower thermal losses and saves power. With the high-current applications, using the MOSFETs with lowest on-resistance allows for reduction of number of MOSFETs connected in parallel, reduces costs, and results in smaller overall solutions.

Limitation of the second inrush current spike can be realized using several methods including direct control of the current and/or control of power dissipated on the MOSFET Q₁. The advantage of controlling the power dissipated on the MOSFET Q₁ is that this method can combine the thermal and overcurrent protection into one circuit, essentially adding the thermal protection feature to the current limiting function. With this method, the current limit Iₗᵢₘ can be set as follows:

$${I}_{lim} = \sqrt{\frac{PWR}{{R}_{ds \_ on}}} \qquad ( 5 )$$

where R_{ds}_{_}ₒₙ stands for MOSFET Q₁ channel resistance when on.

It should be apparent from the foregoing description that various exemplary embodiments of the invention may be implemented in hardware. Furthermore, various exemplary embodiments may be implemented as instructions stored on a non-transitory machine-readable storage medium, such as a volatile or non-volatile memory, which may be read and executed by at least one processor to perform the operations described in detail herein. A non-transitory machine-readable storage medium may include any mechanism for storing information in a form readable by a machine, such as a personal or laptop computer, a server, or other computing device. Thus, a non-transitory machine-readable storage medium may include read-only memory (ROM), random-access memory (RAM), magnetic disk storage media, optical storage media, flash-memory devices, and similar storage media and excludes transitory signals.

It should be appreciated by those skilled in the art that any blocks and block diagrams herein represent conceptual views of illustrative circuitry embodying the principles of the invention. Implementation of particular blocks can vary while they can be implemented in the hardware or software domain without limiting the scope of the invention. Similarly, it will be appreciated that any flow charts, flow diagrams, state transition diagrams, pseudo code, and the like represent various processes which may be substantially represented in machine readable media and so executed by a computer or processor, whether or not such computer or processor is explicitly shown.

Accordingly, it is to be understood that the above description is intended to be illustrative and not restrictive. Many embodiments and applications other than the examples provided would be apparent upon reading the above description. The scope should be determined, not with reference to the above description or Abstract below, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

1. An inrush current controller for controlling inrush current during primary and secondary inrush current phases from a power source to a load, comprising:
a first electronic switch connected between said power source and said load;
a second electronic switch connected in series with a resistive device, wherein the series connected combination is connected between said power source and said load;
a pulse generator which is configured to provide a pulse of a predetermined length that corresponds to the primary inrush current phase; and
control circuitry connected to said pulse generator, wherein said control circuitry, at the commencement of a pulse from said pulse generator, is configured to enable said second electronic switch and, at the cessation of said pulse, is configured to apply a test condition and enable said first electronic switch during the secondary inrush current phase after the test condition is met.

2. The inrush current controller of claim 1, wherein said test condition comprises determining if the voltage across said first electronic switch is below a predetermined level.

3. The inrush current controller of claim 2, wherein said first electronic switch is a first MOSFET.

4. The inrush current controller of claim 3, wherein said control circuitry enables said first MOSFET by modulating the associated gate voltage of said first MOSFET.

5. The inrush current controller of claim 2, further comprising:
a current sensing resistor connected in series with the first electronic switch, wherein the series connected combination is connected between the power source and the load.

6. The inrush current controller of claim 5, wherein enabling of the first electronic switch is modulated to keep the power dissipation of the first electronic switch below a predefined limit.

7. The inrush current controller of claim 5, wherein enabling of the first electronic switch is modulated to keep the current through the first electronic switch below a predefined limit.

8. The inrush current controller of claim 1, wherein said first electronic switch and said second electronic switch are configured to be on the positive voltage rail between the power source and the load.

9. The inrush current controller of claim 1, wherein said first electronic switch and said second electronic switch are configured to be on the negative voltage rail between the power source and the load.

10. A method for controlling inrush current during primary and secondary inrush current phases from a power source to a load, comprising:
generating, by a pulse generator, a pulse of a predetermined length that corresponds to the primary inrush current phase; and
controlling, by control circuitry, a first electronic switch between said power source and said load and a second electronic switch in series with a resistive device, wherein the series connected combination is connected between said power source and said load;
enabling said second electronic switch at the commencement of a pulse from said pulse generator;
applying a test condition at the cessation of said pulse; and
enabling said first electronic switch during the secondary inrush current phase after the test condition is met.

11. The method of claim 10, wherein said test condition comprises determining if the voltage across said first electronic switch is below a predetermined level.

12. The method of claim 11, wherein said first electronic switch is a first MOSFET.

13. The method of claim 12, wherein said control circuitry enables said first MOSFET by modulating the associated gate voltage of said first MOSFET.

14. The method of claim 11, further comprising a current sensing resistor connected in series with the first electronic switch wherein the series connected combination is connected between the power source and the load.

15. The method of claim 14, wherein enabling of the first electronic switch is modulated to keep the power dissipation of the first electronic switch below a predefined limit.

16. The method of claim 14, wherein enabling of the first electronic switch is modulated to keep the current through the first electronic switch below a predefined limit.

17. The method of claim 10, wherein said first electronic switch and said second electronic switch are configured to be on the positive voltage rail between the power source and the load.

18. The method of claim 10, wherein said first electronic switch and said second electronic switch are configured to be on the negative voltage rail between the power source and the load.
